(19) United States
(12) Patent Application Publication
(10) Pub. No.: US 2011/0204517 A1
(43) Pub. Date: Aug. 25, 2011

(54) Semiconductor Device with Vias Having More Than One Material

(75) Inventors: Shiqun Gu, San Diego, CA (US); Yiming Li, San Diego, CA (US); Steve J. Bezuk, San Diego, CA (US)

(73) Assignee: QUALCOMM INCORPORATED, San Diego, CA (US)

(21) Appl. No.: 12/710,399

(22) Filed: Feb. 23, 2010

(51) Int. Cl. H01L 23/48; H01L 21/768; H01L 21/50

(52) U.S. Cl. 257/751; 438/653; 438/107; 257/E23.011; 257/E21.597; 257/E21.499

(57) ABSTRACT

A semiconductor die includes a via within a substrate material of the semiconductor die. The via includes a first conductive material having a first Coefficient of Thermal Expansion (CTE) and a second conductive material between the first conductive material and the substrate material of the semiconductor die. The second conductive material has a second CTE between the first CTE and a CTE of the substrate material of the semiconductor die. The first conductive material can be copper. The second conductive material can be tungsten and/or nickel. The substrate material can be silicon.

### TECHNICAL FIELD

The present description relates, in general, to vias and, more specifically, to vias having two or more conductive materials therein.

### BACKGROUND

Many devices currently use chip packages that have two or more chips (e.g., a processor chip and a memory chip) that are stacked. Some conventional designs use Through Silicon Vias (TSVs) to couple the chips together. As their name suggests, TSVs are generally substantially vertical interconnects used to make electrical connections through a semiconductor. TSVs can be used to couple devices within the same die or in different but adjacent (e.g., stacked) dies. Ideally, a via should have low resistance since it carries signals between the chips. Many conventional TSVs use copper for a conductor because of its low resistance. However, the use of copper presents some challenges.

One challenge is that some conventional TSV fabrication techniques use a barrier/seed deposition process to couple the copper material to the inside surface of the vias. The barrier/seed deposition process is usually performed with Physical Vapor Deposition (PVD), which can be a high-cost and technically challenging process.

Another challenge with using copper is that the Coefficient of Thermal Expansion (CTE) of copper is around sixteen ppm per degree Celsius. By contrast, silicon (a common material for semiconductor substrates) has a CTE of around three ppm per degree Celsius; thus, there is a factor of five or six difference between the CTEs of the two materials. When a chip is subject to thermal cycling, the copper will bend more than silicon bends so that the copper material in a via may “pop up” affecting material above the via. In some instances, thermal changes in the shape of copper materials of vias have caused delamination with low-K dielectric layers, and even breaking metal lines that couple to vias. Moreover, delamination occurs between the copper in the vias and silicon dioxide liners in the vias.

FIG. 1 is an illustration of a conventional TSV 100. The TSV 100 includes copper that interfaces with the silicon 102 and with the item 101. The copper interfaces with the silicon 102 through an insulating liner 103, such as Tetraethylorthosilicate (TEOS). The item 101 can include anything that is placed above the TSV 100, such as a low-K dielectric layer, a metal line, and/or the like. FIG. 1 is not drawn to scale, as a conventional TSV may be 50 to 100 microns tall and six microns in diameter, whereas a metal line on top of a TSV may be about 0.2 microns thick.

In FIG. 1, the TSV 100 has expanded due to thermal changes, and its expansion has affected the item 101 by pushing the item 101 away from the silicon 102, a phenomenon referred to as “delamination.” Delamination can also occur at the interface of the silicon 102 and the copper of the TSV 100. Furthermore, the deformation of the item 102 can result in breaking in some instances due to the steep ninety degree drop from the copper of the TSV 100 to the silicon 102.

One proposal to avoid the disadvantages of copper is to use a different material, such as tungsten. Tungsten has a lower CTE than does copper, and the CTE of tungsten is closer to that of silicon, but there is a penalty for using tungsten. Specifically, the resistance of tungsten is higher than that of copper. Also, it can be difficult to form a larger diameter via using tungsten because tungsten is usually deposited with a CVD plasma process. Using CVD plasma processes, there is a maximum thickness of about one micron, which can be inadequate for a six micron via.

### BRIEF SUMMARY

According to one embodiment, a semiconductor die includes a via within a substrate material of the semiconductor die. The via includes a first conductive material having a first Coefficient of Thermal Expansion (CTE) and a second conductive material between the first conductive material and the substrate material of the semiconductor die. The second conductive material has a second CTE between the first CTE and a CTE of the substrate material of the semiconductor die.

According to another embodiment, a method for fabricating a via within a semiconductor die includes removing semiconductor material to create a hole through a substrate of the semiconductor die. The method further includes depositing a first conductive material, having a first coefficient of thermal expansion (CTE), within the hole and depositing a second conductive material, having a second CTE, over at least a portion of the first conductive material. The first CTE is between the second CTE and a CTE of the substrate of the semiconductor die.

According to another embodiment, a method for fabricating a via within a semiconductor die includes the step of removing semiconductor material to create a hole through a substrate of the semiconductor die. The method further includes the steps of depositing a first conductive material, having a first coefficient of thermal expansion (CTE), within the hole and depositing a second conductive material, having a second CTE, over at least a portion of the first conductive material. The first CTE is between the second CTE and a CTE of the substrate of the semiconductor die.

According to yet another embodiment, a semiconductor die has a via within a substrate material of the semiconductor die. The via includes first means for conducting electrical signals having a first Coefficient of Thermal Expansion (CTE) and second means for conducting electrical signals between the first conducting means and the substrate material of the semiconductor die. The second conducting means has a second CTE between the first CTE and a CTE of the material of the semiconductor die.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is an illustration of a conventional TSV.

FIG. 2 is an illustration of a portion of an exemplary semiconductor die adapted according to one embodiment of the disclosure.

FIG. 3 is an illustration of an exemplary TSV adapted to one embodiment of the disclosure.

FIG. 4 is an illustration of the exemplary process adapted for fabricating a TSV in a semiconductor device according to one embodiment of the disclosure.

FIG. 5 shows an exemplary wireless communication system in which an embodiment of the disclosure may be advantageously employed.

### DETAILED DESCRIPTION

FIG. 2 is an illustration of a portion of an exemplary semiconductor die 200 adapted according to one embodiment. FIG. 2 illustrates a cut-away view of a portion of the semiconductor die 200. The semiconductor die 200 includes, among other things, a Through Silicon Via (TSV) 210, a transistor 220, low-K dielectric layers 203 and 204, and a semiconductor (e.g., silicon) substrate 201. Insulator layers 205, 206, as well as a dielectric 202 are also provided. The layer 207 is a wafer backside passivation to insulate wafer backside metal (not shown) from the substrate 201. The material can be silicon oxide or silicon nitride. While FIG. 2 is shown with reference to silicon as the substrate material, it is understood that various embodiments can be adapted to devices using other materials, such as gallium arsenide, glass, organic materials, and the like. It is also understood that various embodiments are adaptable to vias in general and are not limited merely to TSVs. Similarly, although the term “Through Silicon Via” is used, the substrate can be materials other than silicon.

The TSV 210 includes two conductive materials. One conductive material is copper 211, and the other conductive material is a buffer metal 212, which is disposed between the copper 211 and the substrate 201. The buffer metal 212 has a CTE between that of the substrate 201 (i.e., about 3 ppm per degree Celsius for silicon) and that of copper (i.e., 16 ppm per degree Celsius). Various suitable buffer materials include, but are not limited to, tungsten (CTE of about 4.5 ppm per degree Celsius) and nickel (CTE of about thirteen ppm per degree Celsius).

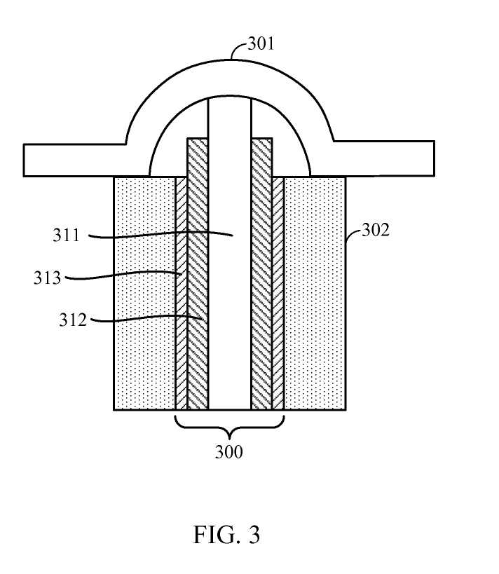

The presence of the buffer metal 212 can provide several structural enhancements. For instance, the stress at the buffer/liner (e.g., tungsten/silicon dioxide) interface and the stress at the filler/buffer (e.g., copper/tungsten) will be reduced due to the intermediate CTE of the buffer metal 212. Also, the pushing force applied by the TSV 210 on items above/below it can be reduced. Both enhancements are explained in more detail with respect to FIG. 3.

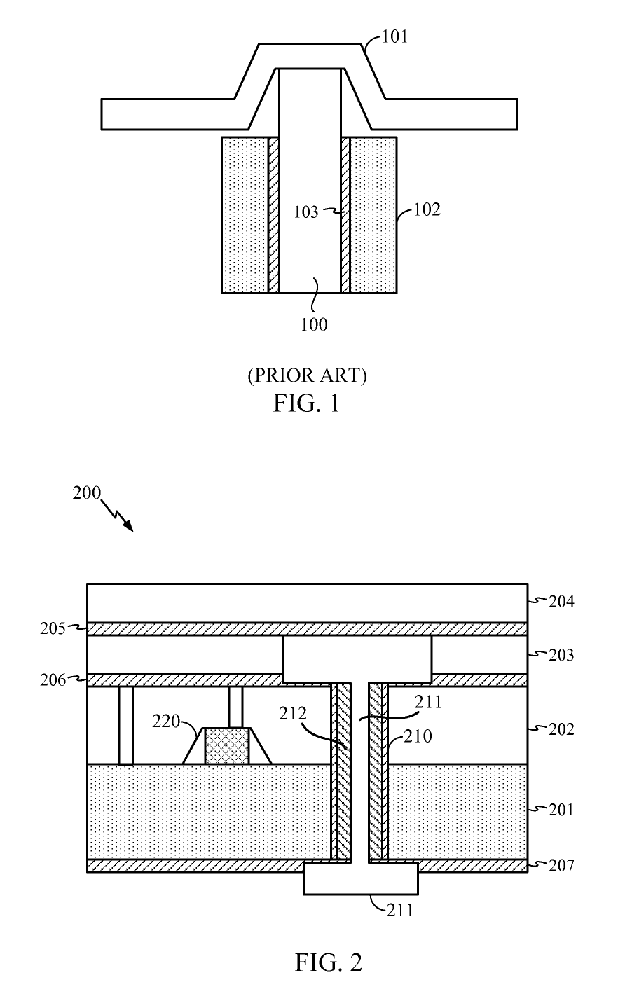

FIG. 3 is an illustration of an exemplary TSV 300 adapted to one embodiment, and it is offered in contrast to the conventional TSV of FIG. 1. The TSV 300 interfaces with the substrate 302 and also interfaces with the item 301. In this example, the TSV 300 interfaces with the substrate 302 through an insulating liner 313, e.g., TEOS. The item 301 generically represents any item that may be coupled to a TSV, such as a low-K dielectric layer, a metal line, and the like. The TSV 300 includes two conductors. The first conductor is a buffer metal 312, such as nickel, tungsten, and/or the like, and the buffer metal 312 interfaces with the substrate 302. The second conductor is the copper 311, which interfaces with the buffer metal 312 and is separated from the substrate 302 by the buffer metal 312.

The TSV 300 includes features that are different than features of the all-copper TSV 100 of FIG. 1. For instance, for the same diameter and same length, the TSV 300 includes less copper than does the TSV 100. Less copper means less thermal expansion for the TSV 300. Furthermore, the TSV 300 has a more gradual CTE transition from the copper 311 to the substrate 302, with the buffer metal 312 providing an intermediate CTE between the copper 311 and the substrate 302. The more gradual transition results in a more gradual deformation of the item 301, thereby improving mechanical reliability by reducing the incidence of breakage and delamination. Additionally, the lower CTE of the buffer metal 312 leads to reduced incidence of delamination between the buffer metal 312 and the via liner, e.g., silicon dioxide, and between the copper 311 and the buffer metal 312.

FIGS. 2 and 3 are not drawn to scale. In one example, the diameter of the TSV 300 is about six microns, the height of the TSV 300 is between fifty and one hundred microns, and the thickness of the item 301 is about 0.2 microns. Continuing with the example, the thickness of the layer of the buffer metal 312 is between about 1 and 1.5 microns so that it is about one-half to one-third of the radius of the TSV 300. While the previous example includes dimensions for some features, the example is intended to be nonlimiting. Other embodiments may include different dimensions for one or more of the features.

Dies according to various embodiments may be fabricated in any of a variety of ways. In one example, a technique called “via first” is performed. The via first method involves forming the TSVs in a substrate before other fabrication of circuitry (e.g., transistors) occurs. A pattern of vias is etched or drilled into a fraction of the depth of the base substrate. The vias are then filled with a buffer metal and another conductive material, such as copper. Circuit fabrication follows, which can include high-temperature processes to properly dope the semiconductor material. The back side of the substrate containing the TSVs is ground down to expose the TSVs.

In a “via last” technique, circuitry fabrication takes place before the TSVs are formed. The circuitry contains interconnect pads that will be coupling points for the TSVs. TSVs are created by either etching or drilling into the pad through the depth of the substrate or etching or drilling from the back side of the substrate to the pad. The TSV is then filled with a buffer metal and another conductive material.

Using a via first technique, the front end of the line processing is performed first, then the vias are fabricated, followed by the back end of the line processing. Using the via last approach, the front end of the line processing is performed first, then back end of the line processing is performed, then vias are fabricated through the stack. Another approach is referred to as “via middle,” in which TSVs are formed after the circuitry is formed but before back end of the line processing is performed. An advantage of via middle and via last techniques is that the TSVs in such techniques are not exposed to the extreme temperatures of the doping process. Various embodiments are not limited to any particular method for fabricating TSVs and semiconductor devices, as any method now known or later developed to fabricate TSVs can be used.

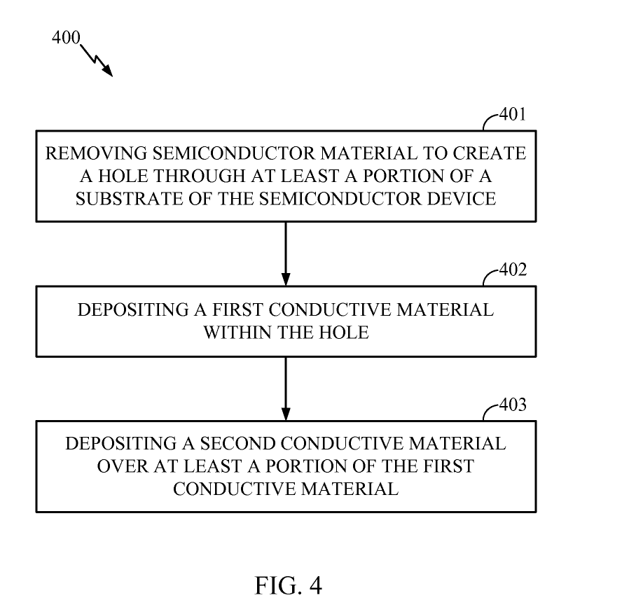

FIG. 4 is an illustration of the exemplary process 400 adapted for fabricating a TSV in a semiconductor die according to one embodiment. In block 401, the semiconductor material is removed to create a hole through at least a portion of a substrate of the semiconductor die. Suitable processes for removing semiconductor material include, but are not limited to, etching and drilling.

In block 402, a first conductive material is deposited within the hole. Various techniques can be used, including PVD techniques and CVD techniques. In embodiments that use tungsten for a buffer metal, plasma CVD may be used, though the scope of embodiments is not limited to tungsten nor to any particular technique for deposition of the first conductive material.

In block 403, a second conductive material is deposited over at least a portion of the first conductive material. In this example, in block 403, the second conductive material is deposited within the space on the inner surface of the first conductive material. Examples of a second conductive material include, but are not limited, to copper and silver. In embodiments that use copper, block 403 may include Electrochemical Plating (ECP) processes to deposit the copper, though the scope of embodiments is not limited to any particular process. In some embodiments, block 403 may include filling in the remainder of the via with the second conductive material.

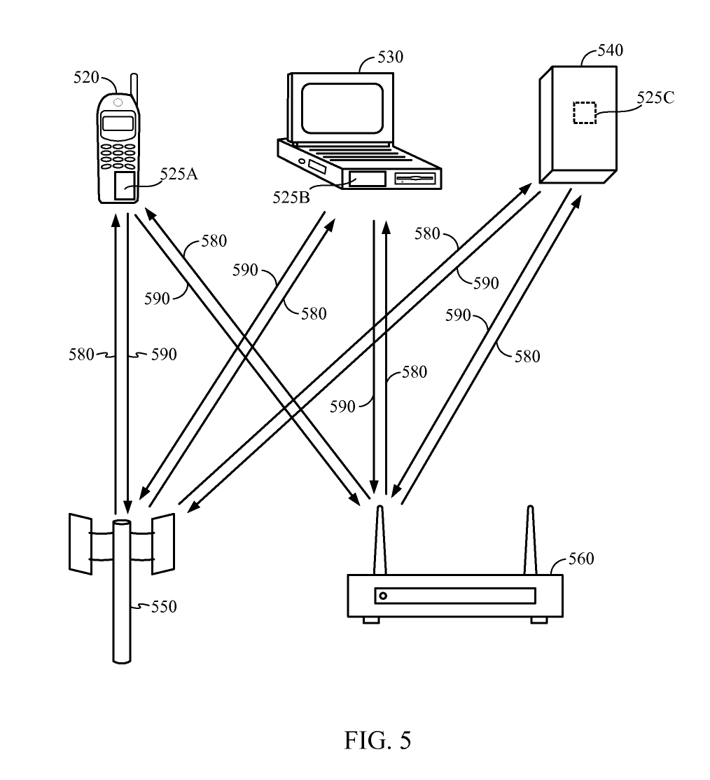

While the method 400 is shown as a series of discrete blocks, the disclosure is not so limited. Various embodiments may add, omit, modify, or rearrange the actions of the blocks 401-403. For instance, any method for fabricating dies can be used, including, e.g., via first, via last, and via middle techniques. Furthermore, some embodiments may include integrating the semiconductor die into a chip package with another die and installing the chip package into a larger device, such as a device shown in FIG. 5.

Moreover, while the examples above show two conductive materials used in a TSV, the scope of embodiments is not so limited. It should be noted that multiple, different layers of buffer metals can be used in other embodiments. Thus, in some embodiments, block 402 may include depositing two or more different buffer materials in the TSV.

Various embodiments may provide one or more advantages over conventional designs that use vias with only a single conductive material. For instance, as mentioned above, various embodiments ameliorate the temperature-induced deformation of vias, thereby reducing the incidence of delamination at interfaces and metal line cracking.

Furthermore, in some embodiments the barrier/seed deposition processes of conventional techniques can be omitted. Specifically, the buffer metal layers themselves can sometimes be used as a barrier and seed. Also, the buffer metal layer deposition can sometimes be performed by various CVD processes (depending on the particular metals used for the buffer layers), which have a lower cost and better step coverage than PVD processes for conventional designs. Improved step coverage performance can facilitate the use of smaller vias, such as those of two microns or less in diameter.

FIG. 5 shows an exemplary wireless communication system 500 in which an embodiment of the disclosure may be advantageously employed. For purposes of illustration, FIG. 5 shows three remote units 520, 530, and 540 and two base stations 550, 560. It will be recognized that wireless communication systems may have many more remote units and base stations. The remote units 520, 530, and 540 include improved semiconductor processor devices 525A, 525B, and 525C, respectively, which in various embodiments include vias according to the embodiments above. In some embodiments, improved semiconductor devices are also included in base stations 550, 560. FIG. 5 shows the forward link signals 580 from the base stations 550, 560 and the remote units 520, 530, and 540 and the reverse link signals 590 from the remote units 520, 530, and 540 to base stations 550, 560.

In FIG. 5, the remote unit 520 is shown as a mobile telephone, the remote unit 530 is shown as a portable computer, and the remote unit 540 is shown as a computer in a wireless local loop system. For example, the remote units may include mobile devices, such as cell phones, hand-held personal communication systems (PCS) units, portable data units such as personal data assistants; the remote units may also include fixed location data units such as meter reading equipment. Although FIG. 5 illustrates remote units according to the teachings of the disclosure, the disclosure is not limited to these exemplary illustrated units. The disclosure may be suitably employed in any device which includes semiconductor chip packages.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor die comprising:
a via within a substrate material of the semiconductor die, the via including a first conductive material having a first Coefficient of Thermal Expansion (CTE) and a second conductive material between the first conductive material and the substrate material of the semiconductor die, the second conductive material having a second CTE between the first CTE and a CTE of the substrate material of the semiconductor die.

2. The semiconductor die of claim 1 in which the material of the semiconductor die comprises at least one of:
glass;
semiconductor material; and
organic material.

3. The semiconductor die of claim 1 in which the material of the semiconductor die comprises silicon having a CTE within of about 16 ppm/° C.

4. The semiconductor die of claim 1 in which the second conductive material includes at least one of nickel and tungsten.

5. The semiconductor die of claim 1 in which the second conductive material has a thickness of about one-third to one-half of a radius of the via.

6. The semiconductor die of claim 1 incorporated into a device selected from a group consisting of a music player, a video player, an entertainment unit, a navigation device, a communications device, a personal digital assistant (PDA), a fixed location data unit, and a computer.

7. The semiconductor die of claim 1 in which the die is integrated into a chip package with another semiconductor die.

8. A method for fabricating a via within a semiconductor die, the method comprising:
removing semiconductor material to create a hole through a substrate of the semiconductor die;
depositing a first conductive material, having a first coefficient of thermal expansion (CTE), within the hole; and
depositing a second conductive material, having a second CTE, over at least a portion of the first conductive material, the first CTE being between the second CTE and a CTE of the substrate of the semiconductor die.

9. The method of claim 8 in which depositing the first conductive material comprises:
performing a Chemical Vapor Deposition (CVD) process.

10. The method of claim 8 in which the first conductive material includes at least one of nickel and tungsten.

11. The method of claim 8 in which depositing the second conductive material comprises:
performing an Electrochemical Plating (ECP) process to deposit copper on a surface of the first conductive material.

12. The method of claim 8 in which the semiconductor die comprises at least one transistor coupled to a metal line by the via, the method comprising:
fabricating the transistor before fabricating the via followed by fabricating the metal line.

13. The method of claim 8 further comprising incorporating the semiconductor die into an item selected from a group consisting of a music player, a video player, an entertainment unit, a navigation device, a communications device, a personal digital assistant (PDA), a fixed location data unit, and a computer.

14. The method of claim 8 further comprising integrating the semiconductor die into a chip package with another semiconductor die.

15. A method for fabricating a semiconductor die, the method comprising the steps of:
removing semiconductor material to create a hole through a substrate of the semiconductor die;
depositing a first conductive material, having a first coefficient of thermal expansion (CTE), within the hole; and
depositing a second conductive material, having a second CTE, over at least a portion of the first conductive material, the first CTE being between the second CTE and a CTE of the substrate of the semiconductor die.

16. The method of claim 15 further comprising the step of:
incorporating the semiconductor die into an item selected from a group consisting of a music player, a video player, an entertainment unit, a navigation device, a communications device, a personal digital assistant (PDA), a fixed location data unit, and a computer.

17. The method of claim 15 further comprising the step of:
integrating the semiconductor die into a chip package with another semiconductor die.

18. A semiconductor die having a via within a substrate material of the semiconductor die, the via comprising first means for conducting electrical signals having a first Coefficient of Thermal Expansion (CTE) and second means for conducting electrical signals between the first conducting means and the substrate material of the semiconductor die, the second conducting means having a second CTE between the first CTE and a CTE of the material of the semiconductor die.

19. The semiconductor die of claim 18 in which the first conducting means comprises copper.

20. The semiconductor die of claim 18 in which the second conducting means comprises at least one of nickel and tungsten.

21. The semiconductor die of claim 18 incorporated into a device selected from a group consisting of a music player, a video player, an entertainment unit, a navigation device, a communications device, a personal digital assistant (PDA), a fixed location data unit, and a computer.

22. The semiconductor die of claim 18 in which the die is integrated into a chip package with another semiconductor die.
